(19) United States
(12) Patent Application Publication
(10) Pub. No.: US 2006/0154393 A1
(43) Pub. Date: Jul. 13, 2006

(54) Systems and methods for removing operating heat from a light emitting diode

(76) Inventors: Trung Tri Doan, Los Gatos, CA (US); Chuong Anh Tran, Orange, CA (US)

Correspondence Address: LEWIS L. LOCKWOOD;LEWIS AND ROCA LLP, 40 NORTH CENTRAL AVENUE, PHOENIX, AZ, 85004, US

(21) Appl. No.: 11/032,855

(22) Filed: Jan. 11, 2005

(51) Int. Cl. H01L 21/50

(52) U.S. Cl. 438/26; 438/122

(57) ABSTRACT

Systems and methods for fabricating a light emitting diode include forming a multilayer epitaxial structure above a carrier substrate; depositing at least one metal layer above the multilayer epitaxial structure and forming heat removal fins thereon; removing the carrier substrate.

The present invention generally relates to a light-emitting diode and a method for fabricating the same.

Light-emitting diodes (LEDs) are playing an increasingly important role in our daily life. Traditionally, LEDs are become ubiquitous in many applications, such as communications and other areas, such as mobile phones, appliances and other electronic devices. Recently, the demand for nitride based semiconductor materials (e.g., having Gallium Nitride or GaN) for opto-electronics has increased dramatically for applications such as video displays, optical storage, lighting, medical instruments, for-example. Conventional blue light-emitting diodes (LEDs) are formed using semiconductor materials of nitride, such as GaN, Al GaN, InGaN and AIInGaN. Most of the semiconductor layers of the aforementioned-typed light emitting devices are epitaxially formed on electrically non-conductive sapphire substrates. Since the sapphire substrate is an electrically insulator, electrodes cannot be directly formed on the sapphire substrate to drive currents through the LEDs. Rather, the electrodes directly contact a p-typed semiconductor layer and an n-typed semiconductor layer individually, so as to complete the fabrication of the LED devices. However such configuration of electrodes and electrically non-conductive nature of sapphire substrate represents a significant limitation for the device operation. For example, a semi-transparent contact needs to be formed on the p-layer to spread out the current from p-electrode to n-electrode. This semi-transparent contact reduces the light intensity emitted from the device due to internal reflectance and absorption. Moreover, p and n- electrodes obstruct the light and reduce the area of light emitting from the device. Additionally, the sapphire substrate is a heat insulator (or a thermal insulator) and the heat generated during the device operation can not be effectively dissipated, thus limiting the device reliability. Thus, limitations of conventional LED structures include: (1) Semi-transparent contact on p-layer 5 is not 100% transparent and can block the light emitted from layer 4; (2) current spreading from n-electrode to p-electrode is not uniform due to position of electrodes; and (3) heat is accumulated during device operation since sapphire is a thermal and electrical insulator.

### SUMMARY

In one aspect, a method for fabricating a light emitting diode includes forming a multilayer epitaxial structure above a carrier substrate; depositing at least one metal layer above the multilayer epitaxial structure and forming heat removal structures on the metal (such as surface fins or bums using roughening process) thereon; and removing the carrier substrate.

Implementations of the above aspect may include one or more of the following. The carrier substrate can be sapphire. The deposition of the metal layer does not involve bonding or gluing the metal layer to a structure on the substrate. The depositing of the metal layer can apply using Electro chemical deposition, electroless chemical deposition, CVD chemical vapor deposition, MOCVD Metal Organic CVD, PECVD Plasma enhance CVD, ALD Atomic layer deposition, PVD Physical vapor deposition, evaporation, or plasma spray, or the combination of these techniques. The metal layer can be single or multi-layered. In case that the metal layer is a multi-layer, a plurality of metal layers with different composition can be formed and the layers could be deposited using different techniques; In one embodiment, the thickest layer is deposited using electro or electroless chemical deposition. The heat removal structures can be formed into the metal layers using etching techniques, laser technique, saw technique, roughening technique. For the etching techniques, one could use wet or dry etching with or without a masking layer. For the laser technique, one could scribe into the metal layers (without cutting through) with various patterns optimized for efficient heat removal by increasing the effective surface area. For sawing techniques, one could saw into the metal layers (without cutting through) with various patterns optimized for efficient heat removal by increasing the effective surface area. The effective surface area is the area with topography comparing to a planar surface without topography (Effective surface area A=(topography surface increase factor)x (flat surface area). For the roughening techniques, the metal is roughen using sand blasting, grinding, wet or dry etching with a mask to transfer the roughness into the metal surface. The carrier substrate removal can be done using laser, etching, grinding/lapping or chemical mechanical polishing or wet etching, among others. The carrier substrate can be sapphire, GaAs, SiC, and Si, among othes.

In another aspect, a method for fabricating a light emitting diode wafer includes providing a carrier substrate; depositing a multilayer epitaxial structure; depositing one or more metal layers above the multilayer epitaxial structure; defining one or more mesas using etching; forming one or more non-conductive layers; removing a portion of the non conductive layers; depositing at least one or more metal layers ; removing the carrier substrate; forming a heat removing structure having the effective surface area greater than 1.1 of the original surface.

Implementations of the above aspect can include one or more of the following. The metal layers could have same or different composition and deposited using various deposition techniques. The carrier substrate removal can be done using laser, etching, grinding/lapping or chemical mechanical polishing or wet etching, among others. The carrier substrate can be sapphire, silicon carbide, silicon or gallium arsenide. The multi layer epitaxial structure can be a n-type GaN layer, one or more quantum wells with InₓAl_{y}GaN/GaN layers, and a p-type GaN layer. The one or more metal layers above the multi layer epitaxial structure can be Indium Tin Oxide (ITO), Ag, Al, Cr, Ni, Au, Ti, Ta, ,TiN, TaN, Mo, W, a refractory metal, or a metal alloy, or a composite. An optional doped semiconductor layer can be formed between the multi layer epitaxial structure and the metal layers. The mesa can be defined using a polymer (for example: resist) or a hard mask (for example: SiO2, Si3N4, Aluminum). The non-conductive layer can be SiO₂, Si₃N₄, a diamond element, a non-conducting metal oxide element or a ceramic element or a composite of these materials; The non-conductive layer could be a single layer or could have a plurality of non-conductive layers (for example: SiO2 on Si3N4). In one implementation, the non-conductive layer is the sidewall layer or passivation layer. A portion of the non conductive layer can be removed by lifting off, chemical mechanical polishing (CMP) or dry etching to expose a conductor layer with or without using a masking layer. The conductor layer can be one or more metal layers. The one or more metal layers can be deposited using sputtering, physical vapor deposition (PVD), chemical vapor deposition (CVD), plasma enhanced CVD (PECVD), evaporation, ion beam deposition, electrochemical deposition, electroless chemical deposition, plasma spray, or ink jet deposition. The metal layer can include chromium (Cr), nickel (Ni), Copper, molybdenum (Mo), tungsten (W), Ag, Pt, Zn, Al or a metal alloy. One or more of the additional metal layers can be formed by electro plating or electroless plating. The additional metal layer can be copper (Cu), nickel (Ni), gold (Au), aluminum (Al), silver (Ag), Zinc (Zn), Chrome (Cr), Platinum (Pt)or an alloy thereof. A conductive passivation layer can be deposited, and can be a metal, nickel (Ni), chromium (Cr), or zinc (Zn). The heat removal structures can be formed into the metal layers using etching techniques, laser technique, saw technique, roughening technique. For the etching techniques, one could use wet or dry etching with or without a masking layer. For the laser technique, one could scribe into the metal layers (without cutting through) with various patterns optimized for efficient heat removal by increasing the effective surface area.. For sawing techniques, one could saw into the metal layers (without cutting through) with various patterns optimized for efficient heat removal by increasing the effective surface area. The effective surface area is the area with topography comparing to a planar surface without topography (Effective surface area A=(topography surface increase factor)x (flat surface area). For the roughening techniques, the metal is roughen using sand blasting, grinding, wet or dry etching with a mask to transfer the roughness into the metal surface. The carrier substrate removal can be done using laser, etching, grinding/lapping or chemical mechanical polishing or wet etching, among others. The carrier substrate can be sapphire, GaAs, Si, SiC.

In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Cu, Ni, Ag, Pt or Cr. For electrochemical deposition of copper, a seed layer is deposited using CVD, MOCVD, PVD, ALD, or evaporation process with Au, Cu, Cr or Ni, among others.

In another method for fabricating a light emitting diode, the process includes providing carrier substrate; depositing a multilayer epitaxial structure; depositing one or more metal layers above the multilayer epitaxial structure; etching one or more mesas; forming one or more non conductive layers; removing a portion of the non conductive layers; depositing one or more metal layers and forming heat removal structures thereon; removing the carrier substrate.

Implementations of the above method may include one or more of the following. The metal layers could have same or different composition and deposited using various deposition techniques. The depositing the metal layer can be electro deposition or electroless deposition. The depositing the metal layer can include CVD, PECVD, PVD, e-beam evaporation, or plasma spray. Electrodes can be placed on the multilayer structure. One or more additional metal layers can be formed above the original metal layer. The carrier substrate removal can be done using laser, etching, grinding/lapping or chemical mechanical polishing or wet etching, among others. The carrier substrate can be sapphire, GaAs, SiC, Si.

In a further aspect, a method for fabricating a light emitting diode includes forming a multi layer epitaxial structure above a substrate (such as a sapphire substrate, for example), depositing a metal layer above the epitaxial layer (using electro or electroless plating), removing the substrate (using laser lift-off technique, for example) to expose the n-GaN surface, depositing a metal layer (making contact to n-GaN) above the n-GaN surface and forming heat removal structures.

In one implementation, the multi-layer epitaxial structure includes a reflective metal layer coupled to the metal plating layer; a passivation layer coupled to the reflective metal layer; a p-GaN layer coupled to the passivation layer; a multi-quantum well (MQW) layer coupled to the p-GaN layer; a n-GaN layer coupled to the MQW layer; an n-electrode coupled to the n-GaN layer.

The metal layer can be single or multi-layered. In case that the metal layer is a multi-layer, a plurality of metal layers with different composition can be formed and the layers could be deposited using different techniques. In embodiment, the thickest layer is deposited using electro or electroless chemical deposition

In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Ni or Cu. For electrochemical deposition of copper, a seed layer is deposited using CVD, MOCVD, PVD, ALD, or evaporation process with Au, Cu or Ni, among others.

In yet another aspect, a method for fabricating a light emitting diode, includes forming a multi-layer epitaxial structure over a sapphire substrate, wherein the multi-layer epitaxial structure comprises a multi-quantum well (MQW) layer; coating a metal plating layer above the multi-layer epitaxial structure; removing the sapphire substrate; and providing an n-electrode on the surface of the multi-layer structure and forming heat removal structures on the metal plating layer thereon.

Implementations of the above aspect may include one or more of the following. The metal plating layer can be formed by electroplating. The metal plating layer can also be formed using electroless-plating and by protecting the sapphire substrate with a organic layer or polymer layer. The sapphire substrate can be removed using laser lift-off (LLO) technique. The multilayer epitaxial layer can be a reflective metal layer coupled to the metal plating layer; a passivation layer coupled to the reflective metal layer; a p-GaN layer coupled to the passivation layer; a n-GaN layer coupled to the MQW layer; an n-electrode coupled to the n-GaN layer.

In another aspect, a vertical device structure for a light-emitting device(LED) can be fabricated by forming a multi-layer epitaxial structure over a sapphire substrate, wherein the multi-layer epitaxial structure comprises an multi-quantum well (MQW) active layer; coating a metal plating layer above the multi-layer epitaxial structure; removing the sapphire substrate; and providing an n-electrode on the surface of the multi-layer structure.

The metal layer can be single or multi-layered. In case that the metal layer is a multi-layer, a plurality of metal layers with different composition can be formed and the layers could be deposited using different techniques. In embodiment, the thickest layer is deposited using electro or electroless chemical deposition

In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Ni or Cu. For electrochemical deposition of copper, a seed layer is deposited using CVD, MOCVD, PVD, ALD, or evaporation process with Au, Cu or Ni, among others.

In yet another aspect, a vertical LED includes a multilayer epitaxial layer formed above a temporary substrate; a metal plating layer formed above the multilayer epitaxial layer, wherein the temporary substrate is removed to expose n-GaN surface using laser-lift-off after forming the metal plating layer; one or more conductive layers formed above the n-GaN surface; form n-electrode by etching the conductive layers with a mask; remove the mask to expose the n-electrode; form the heat removal structures on the metal plating layer.

In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Ni or Cu. For electrochemical deposition of copper, a seed layer is deposited using CVD, MOCVD, PVD, ALD, or evaporation process with Au, Cu or Ni, among others. Cr/Au is used as n-electrode (Cr contacting n-GaN).

In another aspect, a vertical light emitting diode includes a metal plating layer; a reflective metal layer coupled to the metal plating layer; a passivation layer coupled to the reflective metal layer; a p-GaN layer coupled to the passivation layer; a multi-quantum well (MQW) layer coupled to the p-GaN layer; a n-GaN layer coupled to the MQW layer; an n-electrode coupled to the n-GaN layer; and a p-electrode coupled to the metal plating layer and forming heat removal fins thereon.

In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Ni or Cu. For electrochemical deposition of copper, a seed layer is deposited using CVD, MOCVD, PVD, ALD, or evaporation process with Au, Cu or Ni, among others. Cr/Au is used as n-electrode (Cr contacting n-GaN).

The invention can be implemented to realize one or more of the following advantages, alone or in various possible combinations. The heat removal structures provide efficient heat sinks that lower the temperature of the device during operation. Since the heat removal structures is part of the LED subtrate, the heat is removed faster away from the junction. Performance of the LED can be improved. The lifespan and reliability of the LED can be improved.

Additionally, the metal substrate can dissipate more heat than the sapphire substrate, so more current can be used to drive the LED. The resulting LED can replace the conventional LED at a smaller size. For the same LED size, the light output from vertical LED is significantly higher than the conventional LED. One implementation includes all of the above described advantages.

### BRIEF DESCRIPTION OF THE DRAWINGS

To better understand the other features, technical concepts and objects of the present invention, one may clearly read the description of the following preferred embodiments and the accompanying drawings, in which:

FIGS. 1-9 show operations in an exemplary process to fabricate another embodiment of a vertical LED with improved heat dissipation.

### DESCRIPTION

In reading the detailed description, the accompanying drawings may be referenced at the same time and considered as part of the detailed description. In the description, the reference numerals given for the inventive device structure will be also used in the recitation of the steps of the inventive manufacturing method.

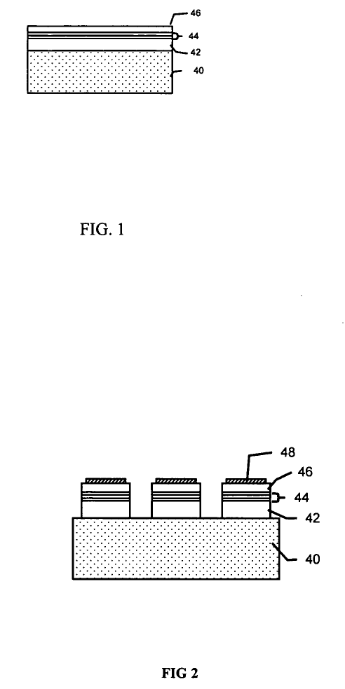

Referring to FIGS. 1 to 9, a manufacturing method for an embodiment of a vertical LED with heat dissipation fins is illustrated therein. The process described below is for one embodiment with InₓAl_{y}GaN LEDs initially grown on sapphire. Electroplating is then used to deposit a thick contact for electrical and thermal conduction for the resulting LED device. Electroplating is used in lieu of wafer bonding. The process can be applied to any optoelectronic device where bonding was used to attach the epilayer to a new host substrate for improvement of optical, electrical and thermal properties.

Turning now to the diagrams, FIG. 1 shows a multi-layer epitaxial structure of an exemplary InAlGaN LED on a carrier 40, which can be a sapphire substrate in one embodiment. The multi-layer epitaxial structure formed above the sapphire substrate 40 includes an n-GaN based layer 42, an MQW active layer 44 and a contact layer 46. The n-GaN based layer 42 may be a doped n-GaN based layer, such as one doped with Si for electricity conduction, having a thickness of about 4 microns, for example.

The MQW active layer 44 can be an InGaN/GaN (or InₓAl_{y}GaN/GaN) MQW active layer. Once an electric power is fed between the n-GaN based layer 42 and the contact=layer 46, the MQW active layer 44 may be excited and thus generates a light. The produced light can have a wavelength between 250 nm to 600 nm. The p-layer can be a p⁺-GaN based layer, such as a p⁺-GaN, a p⁺-InGaN or a p⁺-AlInGaN layer and the thickness thereof may be between 0.01-0.5 microns.

Next, as shown in FIG. 2, a mesa definition process is performed and p-type transparent contacts 48 are formed above the contact layer 46. The transparent contacts 48 can be ITO, Ni/Au, among others. In addition, direct reflected Ag deposition as a metal contact could be also formed. In FIG. 2, individual LED devices are formed following mesa definition. Ion coupled plasma etching is used to etch GaN into separate devices.

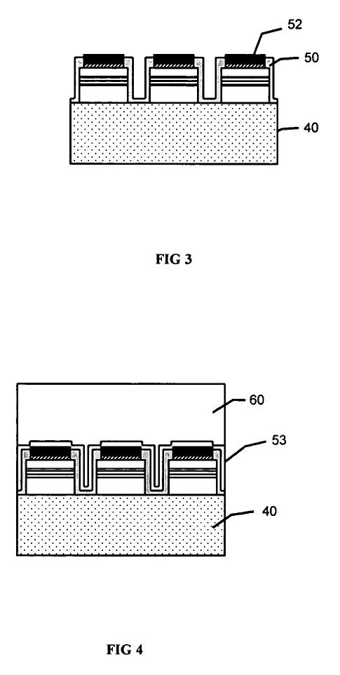

Next, as shown in FIG. 3, a passivation layer 50 is deposited and reflective metal deposition is performed to form a reflective metal 52 such as Al, Ag, and Cr, among others, in a window etched above the passivation layer 50. The passivation layer 50 is non-conductive. The reflective metal 52 forms a mirror surface.

FIG. 4 shows that a thin metal layer 53 (Cr, Cr/Au, Ni/Au, Ti/Au among others) is coated over the structure to serve as a electrode in the electroplating process. However the coating operation is not needed if an electroless process, sputtering or magneto-sputtering process is used in lieu of electroplating. A metal substrate layer 60 is coated thereon.

Turning now to FIG. 5, the multi-layer epitaxial structure is coated with a metal plating layer 60 using techniques such as electroplating and electroless-plating. With electroless-plating, the sapphire substrate 40 is protected using a organic or polymer layer or a coating that can be easily removed without damaging the sapphire or the electroless plated metal of a relatively thick metal such as Cu, Ni, Ag or Pt, among others. The metal layer 60 can be one or more metal layers which could be passivated with another conductive material such as Nickel, gold or Chrome to prevent oxidation.

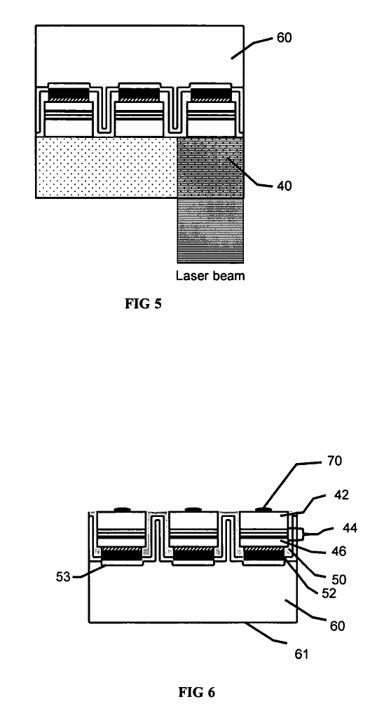

Next, the sapphire substrate 40 is removed. In one embodiment shown in FIG. 6, a laser lift-off (LLO) operation is applied to the sapphire substrate 40. Sapphire substrate removal using laser lift-off is known, reference U.S. Pat. No. 6,071,795 to Cheung et al., entitled, “Separation of Thin Films From Transparent Substrates By Selective Optical Processing,” issued on Jun. 6, 2000, and Kelly et al. “Optical process for liftoff of group III-nitride films”, Physica Status Solidi (a) vol. 159, 1997, pp. R3-R4). Furthermore, highly advantageous methods of fabricating GaN semiconductor layers on sapphire (or other insulating and/or hard) substrates are taught in U.S. patent application Ser. No. 10/118,317 entitled “A Method of Fabricating Vertical Devices Using a Metal Support 5 Film” and filed on Apr. 9, 2002 by Myung Cheol Yoo, and in U.S. patent application Ser. No. 10/118,316 entitled “Method of Fabricating Vertical Structure” and filed on Apr. 9, 2002 by Lee et al. Additionally, a method of etching GaN and sapphire (and other materials) is taught in U.S. patent application Ser. No. 10/118,318 entitled “A Method to Improve Light Output of GaN-Based Light Emitting Diodes” and filed on Apr. 9, 2002 10 by Yeom et al., all of which are hereby incorporated by reference as if fully set forth herein. In other embodiments, the sapphire substrate is removed by wet or dry etching, or chemical mechanical polishing.

As shown in FIG. 6, an n-type electrode/bond pad 70 is patterned on the top of n-GaN layer 42 to complete the vertical LED. In one embodiment, bond pad 70 such as Ni/Cr (Ni is in contact with n-GaN) can be deposited using CVD, PVP or ebeam evaporation; The bond pad 70 is formed by wet or dry etch with a masking layer or using lift-off techniques with a negative masking layer (negative masking layer presents where one does not want to have the materials). A p-electrode and an n-electrode are disposed on the multi-layer epitaxial structure to complete the formation of a vertical GaN-based LED.

The thin metal layer or film 53 is provided as a seeding material purpose of the metal plating layer 60. The thin metal film 53 may be the same or different material with the metal plating layer 60 as long as the metal plating layer 60 may be plated on top of the film 53 using electrochemical deposition or electroless chemical deposition.

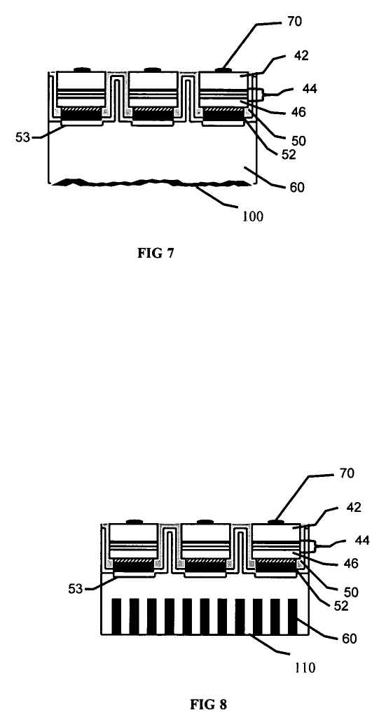

As shown in FIG. 7, the surface of the metal substrate 60 is roughen to creating heat removal structure 100 in such a way that the surface area 100 is more than surface area 61 before roughening; the roughening process can be sand blasting, grinding, scribing or lasering, among others resulting in higher effective surface area 100. In one embodiment, the effective surface area 100 is more than 1.1 that of surface area 61.

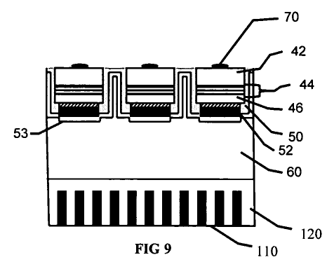

In the process of FIG. 8, the surface of the metal substrate 60 is modified to creating heat removal structures 110 in such a way that the surface area 110 is more than surface area 61 before modified; the modified process can be by etching with a mask, sawing, or laser cut, among others resulting in higher effective surface area 110. In one embodiment, the heat removal structures 110 are fins. In another embodiment, angled fins are arrayed around the metal layer. In other embodiments, the heat sink, heat exchanger, cold plate, and the like can be formed on the metal plating layer 60. The heat sink, heat exchanger, cold plate, and the like have a high thermal conductivity to draw heat from the LED device and transfer it to ambient air.

In the process of FIG. 9, the heat removal structures 120 is prefabricated with heat removal fins 110 before attached to metal substrate 60; the attachment process can be gluing, bonding using paste such as silver paste, among others to provide good thermal conduction. A plurality of heat dissipating elements 110 such as vertically extending fins are etched on the metal plating layer 60. In another embodiment, angled fins are arrayed around the metal layer. In other embodiments, the heat sink, heat exchanger, cold plate, and the like can be formed on the metal plating layer 60. The heat sink, heat exchanger, cold plate, and the like have a high thermal conductivity to draw heat from the LED device and transfer it to ambient air.

The heat dissipation element provides a large surface area for convective dissipation of heat into the environment. The heat dissipation element can have externally projecting features shaped like fins, blades, rudders, sheets, or the like. The degree of heat dissipated by convection can be adjusted by changing the shape or size of the heat dissipation element. For example, increasing the surface area of the externally projecting features without changing their volume typically increases the degree of heat dissipated by convection. The heat can be dissipated from the heat dissipation element by passive convection, for example, due to naturally occurring air movement external to the LED. The heat also can be dissipated from the heat dissipation element by forced convection, for example, air movements created by external fans and/or coolant being pumped through conduits (e.g., tubes) thermally coupled to the heat dissipating element. The configuration of the system can be varied depending on the heat removal requirements of the encased electronic device. For example, the thermal connectors that provide conduction pathways can be made of more conductive materials, shortened, and/or have increased cross sectional area when the heat removal requirements are increased.

Convection involves heat removal by the circulation of one or more fluids, e.g., air, gas, vapor, water, oil, coolant, water ethylglycol (WEG), and the like, around, through, and/or against the LED device, heat sink, heat exchanger, cold plate, and the like. The circulating fluid draws heat from the device, heat sink, heat exchanger, cold plate, and the like, and transports the heat to ambient air.

Alternately, the fins or heat sink body may be any other type of heat sink body or device such as a block of heat conductive material, a heat pipe, a piezoelectric cooler or other heat sink known to those skilled in the art. The shape and size of a particular heat sink are based on the application in which it is used, the design of such being well-known in the art.

Heat removal and thermal control of the LED can be effected further in the design of each fin and the arrangement of the plurality of fins. For example, the width, pitch, length and twist, or skew, angle of each individual fin can be controlled to provide a variety of cooling capabilities. Similarly, the aspect ratio, number of integral fins, dimensions of the metal layer 60, and the arrangement of the plurality of integral fins can be controlled to do the same. Those skilled in the art can appreciate the myriad fin and metal layer 60 patterns that can be used to provide practically any efficacious flow.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for cooling a light emitting diode, comprising:
forming a multilayer epitaxial structure above a carrier substrate;
depositing at least one metal layer above the multilayer epitaxial structure;
removing the carrier substrate; and
forming one or more heat removal structures in the metal layer to dissipate heat.

2. The method of claim 1, wherein the carrier substrate comprises sapphire.

3. The method of claim 1, wherein the depositing metal layer comprises electro chemical deposition.

4. The method of claim 1, wherein the depositing metal layer comprises depositing at least a metal layer followed by one or more electroless chemical depositions.

5. The method of claim 1, wherein depositing metal layer comprising applying using one of: CVD, PECVD, PVD, ALD, MOCVD, evaporation, and plasma spray.

6. The method of claim 1, comprising depositing one or more additional metal layers above the metal layer.

7. The method of claim 1, wherein the heat removal structures comprises roughening.

8. The method of claim 7, wherein the surface roughening comprises applying using one of: sand blasting, grinding, scribing, laser cutting.

9. The method of claim 1, wherein the heat removal structures comprises having a effective surface area greater than approximately 1.1.

10. A method for cooling a light emitting diode, comprising:
forming a multilayer epitaxial structure above a carrier substrate;
depositing at least one metal layer above the multilayer epitaxial structure;
removing the carrier substrate; and
attaching one or more heat removal structures to the metal layer to dissipate heat.

11. The method of claim 10, wherein the carrier substrate comprises sapphire.

12. The method of claim 10, wherein the depositing metal layer comprises electro chemical deposition.

13. The method of claim 10, wherein the depositing metal layer comprises depositing at least a metal layer followed by one or more electroless chemical depositions.

14. The method of claim 10, wherein depositing metal layer comprising applying using one of: CVD, PECVD, PVD, ALD, MOCVD, evaporation, and plasma spray.

15. The method of claim 10, comprising depositing one or more additional metal layers above the metal layer.

16. The method of claim 10, wherein the heat removal structures comprises attaching to the metal substrate using one of: gluing, bonding using paste such as silver paste.

17. The method of claim 10, wherein the heat removal structures comprises having a effective surface area greater than approximately 1.1.

18. A method for fabricating a light emitting diode, comprising:
providing a carrier substrate;
depositing a multilayer epitaxial structure;
depositing one or more metal layers above the multilayer epitaxial structure;
defining one or more mesas using etching;
forming one or more non conductive layers;
removing a portion of the non conductive layers;
depositing at least one or more metal layers and forming one or more heat dissipating fins in the metal layers; and
removing the carrier substrate.

19. The method of claim 7, wherein the carrier substrate comprises one of: sapphire, silicon carbide, silicon, gallium arsenide.

20. The method of claim 7, wherein the multi layer epitaxial structure comprises a n-type GaN or AlGaN layer,
one or more quantum wells with InAlGaN/GaN layers, and
a p-type GaN, AlGaN layer.

21. The method of claim 7, wherein the one or more metal layers above the multi layer epitaxial structure comprises one of: Indium Tin Oxide (ITO), Silver, Al, Cr Ni, Au, Mo, W, a refractory metal, a metal alloy.

22. The method of claim 7, comprising an optional doped semiconductor layer between the multi layer epitaxial structure and the metal layers.

23. The method of claim 7, wherein a mesa comprises one of: a polymer, a hard mask.

24. The method of claim 7, wherein the non-conductive layer comprises one of: SiO₂, Si₃N₄, a diamond like film, a non-conducting metal oxide element, a ceramic element.

25. The method of claim 7, comprising removing a portion of the non conductive layer.

26. The method of claim 7, wherein removing the portion comprises one of: lifting off, wet etching, dry etching to expose a conductor layer.

27. The method of claim 15, wherein the conductor layer comprises one or more metal layers.

28. The method of claim 15, whereas the conductor layer is deposited on top of a passivation layer, wherein the passivation layer comprises one or more non-conductive layers.

29. The method of claim 7, wherein depositing one or more metal layers comprises one of: sputtering, physical vapor deposition (PVD), chemical vapor deposition (CVD), plasma enhanced CVD (PECVD), evaporation-ion beam deposition, electro deposition, electroless deposition, plasma spray, ink jet deposition.

30. The method of claim 7, comprising depositing one or more metal layers using one of: PVD, evaporation-ion beam deposition, CVD, e-beam deposition.

31. The method of claim 19, wherein one metal layer includes one of: chromium (Cr), nickel (Ni), tantalum nitride copper (TaN/Cu), molybdenum (Mo), tungsten (W), a metal alloy.
